(19) United States
(12) Patent Application Publication
(10) Pub. No.: US 2008/0143189 A1
(43) Pub. Date: Jun. 19, 2008

(54) Electrical Circuit Of An Electrolyzer And Method For Reducing The Electromagnetic Fields In The Vicinity Of The Electrolyzer

(75) Inventor: Joachim Lange, Tervuren (BE)

Correspondence Address: OBLON, SPIVAK, MCCLELLAND MAIER & NEUSTADT, P.C., 1940 DUKE STREET, ALEXANDRIA, VA, 22314, US

(73) Assignee: Solvay (Societe Anonyme), Brussels (BE)

(21) Appl. No.: 11/817,232

(22) PCT Filed: Feb. 27, 2006
(86) PCT No.: PCT/EP06/60287

§ 371 Date: Feb. 15, 2008

(51) Int. Cl. H05K 9/00

(52) U.S. Cl. 307/91

(57) ABSTRACT

An electrical circuit for reducing electromagnetic fields in a vicinity of an electrolyzer, including a primary circuit supplying the electrolyzer and a secondary electrical circuit arranged in the vicinity of the primary circuit, for a current to flow in the opposite direction to that current flowing in the main circuit to compensate for electromagnetic fields generated by the main circuit.

The invention concerns electrolyzers, especially to the electrical supply of such electrolyzers.

The invention more especially relates to an electrical circuit for supplying a rectified electrical current to an electrolyzer with bipolar electrodes.

Electrolyzers, in particular with bipolar electrodes, supplied with direct current are commonly used in the electrochemical industry. Such electrolyzers are commonly used for electrolyzing aqueous solutions of sodium chloride with a view to producing chlorine, aqueous solutions of sodium hydroxide or aqueous solutions of sodium chlorate.

In view of the high current densities employed in electrolyzers with bipolar electrodes, a rectified alternating current is generally substituted for the direct current. The rectified alternating current normally has phases whose frequency and amplitude depend on the rectifier being used.

It is furthermore known that high electromagnetic fields, especially those produced by a rectified alternating current, can have detrimental consequences on the human body under extreme conditions, because of the induced currents which they risk generating in the body. It is consequently important to take measures in order to protect the personnel in the vicinity of industrial installations or reduce the strength of the electromagnetic fields there. Standards have moreover being issued in this regard, requiring that the strength of electromagnetic fields in industrial premises be reduced. Among these standards, European standard 89/391/EEC is particularly stringent.

It is an object of the invention to provide an electrical circuit of novel design for supplying an industrial electrolyzer with a heavy electrical current.

It is in particular an object of the invention to provide an electrical circuit with which the electromagnetic field in the vicinity of the electrolyzer is reduced to a sufficiently low value in order to comply with the aforementioned European standard.

It is more particularly an object of the invention to reduce the strength of the electromagnetic field on the gangways running along the side walls of electrolyzers with bipolar electrodes.

The invention consequently relates to an electrical circuit for reducing the electromagnetic fields in the vicinity of an electrolyzer, the electrical circuit comprising a primary electrical circuit, itself comprising the electrolyzer and an electrical line comprising at least one busbar for returning the current flowing in the electrolyzer, and a secondary electrical circuit at least partially arranged in the vicinity of the primary circuit, for a current to flow in the opposite direction to that flowing in the main circuit in order to compensate for the electromagnetic field generated by the primary circuit.

According to the invention, a secondary electrical circuit is arranged in the vicinity of the primary circuit. The current flow in the opposite direction in the secondary circuit is intended to cause a magnetic field which at least partly cancels that created by the current flow in the primary circuit. The secondary circuit must therefore be capable of carrying a current of sufficient strength to obtain the desired compensation. In order to obtain good compensation of the fields, the secondary circuit must be arranged as much as possible in the vicinity of the primary circuit. It is recommended that one part of the secondary circuit should be attached to the electrolyzer and another part should preferably be attached to the busbar or busbars, in order to obtain optimal compensation of the fields, taking into account the structural requirements which may make it necessary to separate the two circuits at certain positions. In order to optimize the compensation, certain segments of the secondary circuit are generally distributed over a plurality of conductors connected in parallel. It is possible to supply the secondary circuit using the supply of the primary circuit, via a control resistor. It is, however, recommended that at least the part of the secondary circuit which lies in the vicinity of the return line should be supplied separately. A separate supply also has the advantage that the frequency of the secondary current can be adapted in order to preferentially eliminate certain particularly problematic frequencies of the magnetic field produced by the electrolyzer. In general, it is recommended that the part of the secondary circuit which lies in the vicinity of the busbar or busbars should carry a current stronger (preferably at least 5 times stronger) than that flowing in the part attached to the electrolyzer, the current ratio being a function of the distance between the busbar and the electrolyzer.

It is also recommended that the part of the circuit lying between the rectifiers and the electrolysis installations should be configured in order to obtain good compensation of the fields. Care will therefore be taken that the current feed and return conductors are close to one another. To this end, it is recommended that these conductors should be branched into a plurality of elements connected in parallel so that these conductors can be interleaved in one another, for example with stacked alternate layers of the elements of each conductor.

The invention applies to any type of electrolyzers such as monopolar or bipolar mercury, diaphragm or membrane electrolyzers. However, it applies more specifically to electrolyzers with substantially vertical bipolar electrodes. Such electrolyzers are well known in engineering, where they are widely used for electrolyzing aqueous solutions of metal halides, particularly sodium chloride. These electrodes are generally formed by a succession of metal frames, each comprising a bipolar electrode, these frames being juxtaposed in the manner of a filter press (Modern Chlor-alkali technology, Volume 3, SCI, 1986, chapter 13 “Operating experience gained with the bipolar Hoechst-Uhde membrane cell”; Modern Chlor-alkali technology, Volume 4, SCI, 1990, chapter 20 “Hoechst-Uhde single element membrane electrolyzer: concept-experiences-applications”). The frames conventionally have a square or rectangular profile so that, when they are juxtaposed in the manner of a filter press, they form an upper wall, a lower or bottom wall and two side walls of the electrolyzer. The electrolyzer is normally supplied with direct current or, more generally, rectified alternating current. The direct or rectified current flows from one terminal of the direct current source or rectifier, through the electrodes, then returns to the other terminal of the direct current source or rectifier via an electrical current line which lies outside the electrolyzer.

The electrical circuit according to the invention is advantageously supplied with rectified alternating current. Three-phase alternating current rectification provides a current whose oscillations have a base frequency six times higher than the fundamental frequency of the three-phase current (for example 6 times 50 Hz) and a complete spectrum of harmonics.

In one recommended embodiment of the invention, the circuit comprises a supply using at least two rectifiers in order to deliver currents whose waveforms are phase-shifted with respect to one another. The electrolysis electrical circuit is advantageously supplied with three-phase alternating current.

The use of at least two mutually phase-shifted rectifiers according to this embodiment makes it possible to increase the frequency of the oscillations of the rectified current supplying the electrolyzer or electrolyzers. Given the strength and the particular arrangement of the currents involved in electrolyzers, the circuit according to the invention makes it possible to substantially reduce the electromagnetic fields emitted in the vicinity of the installation.

In an advantageous variant of this embodiment, the circuit comprises two rectifiers whose phase shift lies between 29° and 31°, preferably close to 30°. In this variant, a current is obtained whose waveforms have a base frequency 12 times higher than the base frequency of the unrectified three-phase current.

In another advantageous variant of this embodiment of the electrical circuit, the circuit furthermore comprises at least one drain coil coupling the outputs of at least two rectifiers. The drain coil is intended to establish an antiparallel reactance between the outputs of the rectifiers. The coil is advantageously formed by assembling plates and sheets of iron, so as to limit the heating losses. The outputs of the rectifiers enter it in opposite directions, so that a current perturbation present in one of the outputs induces by reactance an inverse perturbation in the current coming from the other output. When the two outputs are superimposed by connection in parallel, a less perturbed total current is thereby obtained.

In a preferred variant of the electrical circuit according to the invention, the return electrical current line comprises at least one busbar which is arranged below or above the electrolyzer. The choice of whether to arrange the busbar below or above the electrolyzer is dictated by considerations relating to the construction of the electrolyzer and the assembly mode of the bipolar plates. As a variant, the aforementioned electrical current line may comprise one busbar arranged below the electrolyzer and another busbar which is arranged above the electrolyzer. According to another variant, the electrolyzer may also comprise a plurality of busbars below the electrolyzer and/or a plurality of busbars above the electrolyzer. In practice, for considerations relating to assembly and maintenance of the electrolyzer, it is generally preferred that the aforementioned electrical current line should not comprise a busbar above the electrolyzer.

All other things being equal, it is found that the electrical circuit according to the invention substantially reduces the electromagnetic field in the vicinity of the electrolyzer with bipolar electrodes, principally along its side walls, especially on the gangways which are normally present along these side walls and which are used by the operating and maintenance personnel.

In the electrical circuit according to the invention, the material of the busbar is not critical for the definition of the invention. It is generally made of copper, aluminium or aluminium alloy.

In the electrical circuit according to the invention, the profile of the cross section of the busbar is not critical for the definition of the invention. It may, for example, be square, rectangular, circular or polygonal.

In a first particular embodiment of the electrical circuit according to the invention, the busbar has a rectangular profile and it is oriented so that its large faces are substantially horizontal. All other things being equal, it has been observed that selecting a busbar of rectangular section, arranged horizontally below and/or above the electrolyzer, minimizes the size of the electromagnetic field in the vicinity of the electrolyzer. It has also been observed that the reduction of the electromagnetic field in the vicinity of the electrolyzer is commensurately greater when the ratio between the thickness and the width of the busbar is small. In practice, it is consequently preferred to use a metal plate for the busbar. As a variant, a plurality of metal plates arranged side-by-side below and/or above the electrolyzer may be used.

All other things being equal, it has furthermore been observed that the size of the electromagnetic field in the vicinity of the electrolyzer decreases when the busbar is placed close to the wall of the electrolyzer.

In a second embodiment of the electrical circuit according to the invention, the busbar is consequently arranged in immediate proximity to a wall of the electrolyzer. In this embodiment of the invention, the said wall of the electrolyzer is the lower or bottom wall of the electrolyzer or its upper wall, depending on whether the busbar is located below or above the electrolyzer. In this embodiment of the invention, the expression “in immediate proximity to the wall of the electrolyzer” means that the distance between this wall and the busbar is at most equal to five times (preferably three times) the thickness of the busbar. Preferably, this distance does not exceed the thickness of the busbar.

In a preferred variant of the aforementioned second embodiment of the invention, the busbar is attached to the said wall of the electrolyzer. In this preferred alternative embodiment of the invention, the busbar is advantageously a metal plate of which one of the large faces is attached to the said wall, with only the thickness of the necessary electrical insulators separating the bar from the wall. The metal plate may be attached to a part of the surface area of the said wall. It is preferred that the metal plate should be attached to substantially all of the surface area of the said wall.

In a third particular embodiment of the invention, the aforementioned electrical line furthermore comprises two additional busbars which are respectively arranged in immediate proximity to two side walls of the electrolyzer. In this embodiment of the invention, the expression “in immediate proximity” corresponds to the definition which was given for this expression in the second embodiment explained above.

All other things being equal, the presence of the additional busbars reduces the size of the electromagnetic field in the vicinity of the electrolyzer.

In this third embodiment according to the invention, the additional busbars may have any shape compatible with the construction of the electrolyzer. They may, for example, have a square, rectangular, polygonal, oval or circular profile. The additional busbars may moreover have the same profile or different profiles, and they may have the same dimensions or different dimensions. In practice, however, it is preferred that the additional busbars should have the same profile and the same dimensions. It is furthermore preferred that the additional busbars should have a rectangular profile, and that they should respectively be attached via their large face to the two side walls of the electrolyzer.

In the third embodiment of the invention which has just been described, the respective dimensions of the additional busbars and those of the or each busbar, which is arranged below and/or above the electrolyzer, are determined as a function of the way in which the electrical current is intended to be distributed between these busbars.

In a fourth embodiment of the invention, which is especially advantageous, the return electrical current line of the electrical circuit is positioned so as to generate an electromagnetic field which is substantially symmetrical with respect to the vertical median plane of the electrolyzer. The object of this embodiment (generating an electromagnetic field which is substantially symmetrical with respect to the vertical median plane of the electrolyzer) is achieved by appropriately dimensioning and positioning the or each busbar. The choice of the optimal dimensions and the optimal position is determined by the person skilled in the art, in particular as a function of the shape and the dimensions of the electrolyzer. In practice, this result may generally be obtained by arranging the busbar or the busbars symmetrically with respect to the vertical median plane of the electrolyzer.

The electrical circuit according to the invention substantially reduces the electromagnetic field in the vicinity of the electrolyzer with bipolar electrodes.

Consequently, the invention also relates to a method for reducing the electromagnetic fields in the vicinity of the electrical circuit of an electrolyzer comprising a primary electrical circuit, itself comprising the electrolyzer and an electrical line comprising at least one busbar for returning the current flowing in the electrolyzer, according to which an electrical current is passed through a secondary electrical circuit, arranged in the vicinity of the primary circuit, in the opposite direction to that flowing in the primary circuit.

According to a preferred variant of the method according to the invention, the primary circuit comprises a supply using two rectifiers in order to deliver currents whose waveforms are phase-shifted by 30° with respect to one another.

In an advantageous version of this variant, the primary circuit furthermore comprises a drain coil coupling the outputs of the two rectifiers.

The electrical circuit according to the invention applies especially to electrolyzers for the continuous electrolysis of water or aqueous solutions, such as aqueous solutions of an alkali metal halide, especially sodium chloride. In a preferred embodiment of the invention, the electrolyzer consequently comprises a conduit for the continuous intake of an aqueous electrolyte and a conduit for the continuous discharge of an aqueous electrolyte.

The invention applies in particular to electrolyzers for manufacturing sodium chlorate by electrolyzing aqueous solutions of sodium chloride. The invention applies especially well to electrolyzers for manufacturing chlorine and aqueous solutions of sodium hydroxide by electrolyzing aqueous solutions of sodium chloride, these electrolyzers comprising membranes selectively permeable to cations, which are interposed between the bipolar electrodes.

The electrical circuit according to the invention applies to any electrolysis installation incorporating at least one electrolyzer with vertical bipolar electrodes.

Consequently, the invention also relates to an electrolysis installation comprising at least one electrolyzer with bipolar electrodes, which is connected to an electrical circuit according to the invention. The installation according to the invention may comprise a single electrolyzer, or a plurality of electrolyzers which are connected in electrical series or parallel.

The invention relates in particular to the use of this installation for producing chlorine and aqueous solutions of sodium hydroxide.

Features and details of the invention will become apparent during the following description of the appended figures, which represent some particular embodiments of the invention.

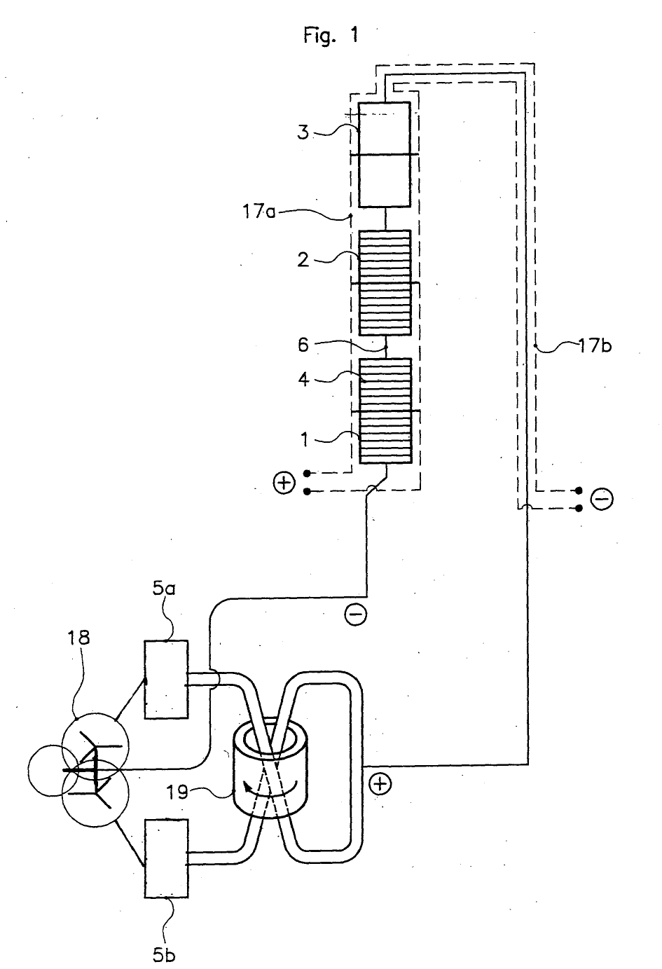

FIG. 1 shows in plan the general layout of an electrolysis installation according to a particular embodiment of the invention;

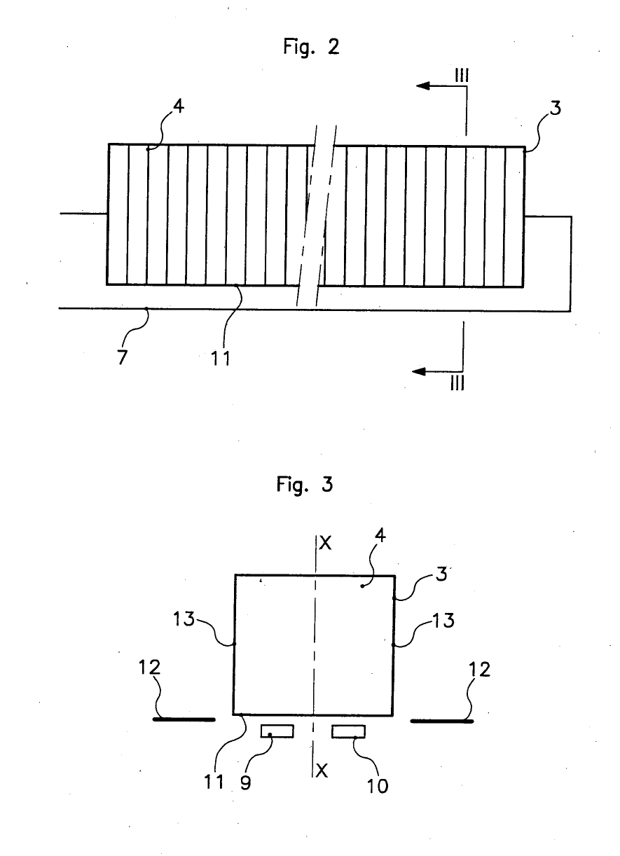

FIG. 2 is a schematic view in longitudinal elevation of another particular embodiment of the electrolysis installation according to the invention;

FIG. 3 is a view in vertical cross section on the plane III-III of FIG. 2;

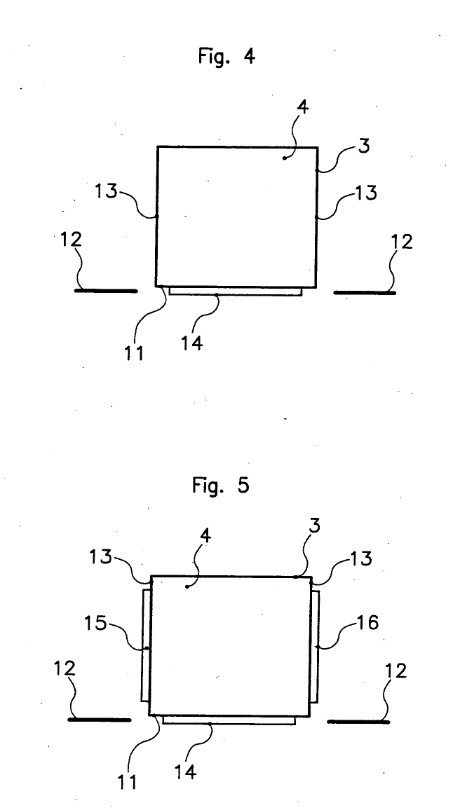

FIG. 4 is a view, similar to FIG. 3, of another embodiment of the installation according to the invention;

FIG. 5 is a preferred variant of the installation in FIG. 4;

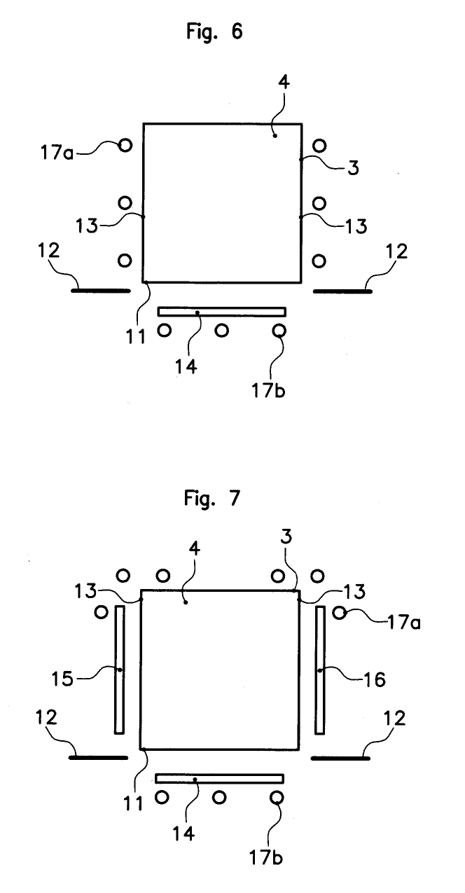

FIGS. 6 and 7 are similar to FIGS. 4 and 5, but they also represent the secondary circuit.

In these figures, identical elements are denoted by the same reference notation.

The electrolysis installation schematized in FIG. 1 comprises three electrolyzers 1, 2 and 3 designed for the production of chlorine, hydrogen and sodium hydroxide by electrolyzing an aqueous solution of sodium chloride. The electrolyzers 1, 2 and 3 are of the type with vertical bipolar electrodes. They are formed by juxtaposing vertical rectangular frames 4, each containing a vertical bipolar electrode (not shown). The frames 4 are juxtaposed in the manner of a filter press. Membranes selectively permeable to cations are interposed between the frames 4 in order to alternately delimit anodic and cathodic chambers. The anodic chambers of the electrolyzers 1, 2 and 3 are in communication with a conduit (not shown) for the continuous intake of an aqueous solution of sodium chloride. They are furthermore in communication with a manifold (not shown) for the continuous discharge of chlorine. The cathodic chambers of the electrolyzers 1, 2 and 3 are in communication with two manifolds (not shown) which are respectively used for the continuous extraction of hydrogen, on the one hand, and an aqueous solution of sodium hydroxide, on the other hand.

The electrolyzers 1, 2 and 3 are coupled in electrical series via a drain coil 19 to two rectifiers 5a and 5b by means of an electrical circuit comprising, on the one hand, conductive bars 6 interposed between the electrolyzers 1, 2 and 3 and, on the other hand, a return electrical current line 7 arranged outside the electrolyzers 1, 2 and 3. The rectifiers 5a and 5b are supplied with a phase shift of 30° by an alternating current source 18.

In the electrolysis installation schematized in FIG. 1, each of the three electrolyzers 1, 2 and 3 may for example comprise from 30 to 40 elementary electrolysis cells, and the electrical supply comprises for example a 520 V direct current rectifier capable of delivering a current of from 8 to 20 kA. As a function of the surface area of the electrodes, this may result in an anodic current density of from 2.5 to 6 kA/m² of anode area. These numerical values, however, are purely indicative and do not limit the scope of the invention and the subsequent claims.

When the bipolar switch is closed, a rectified electrical current flows successively in the electrolyzers 1, 2 and 3, through their bipolar electrodes and into the return line 7. This electrical current generates an electromagnetic field in the environment of the installation.

According to the invention, a secondary circuit comprising segments 17a and 17b is arranged in the vicinity of the electrolyzers and the return line.

The electrolysis installation schematized in FIGS. 2 and 3 illustrates a particular embodiment of the invention. The secondary circuit is not represented in them. Only the electrolyzer 3 has been represented in these figures. In the installation of FIGS. 2 and 3, the return electrical current line 7 comprises two busbars 9 and 10 which are arranged under the lower wall 11 of the electrolyzer 3. The busbars 9 and 10 are prismatic bars of a metal which is a good conductor of electricity (preferably copper or aluminium). These bars are arranged symmetrically on either side of the vertical median plane X-X of the electrolyzer. The bars 9 and 10 are furthermore arranged in the vicinity of the lower wall 11 of the electrolyzer 3. The effect of arranging the busbars 9 and 10 in the way schematized in FIG. 3 is to reduce the size of the electromagnetic field on the gangways 12 which run along the side walls 13 of the electrolyzer 3 and which are intended for the operating personnel of the electrolyzer.

All other things being equal, it has been observed that the strength of the electromagnetic field on the gangways 12 is commensurately less when the bars 9 and 10 are close to the median plane X-X and the lower wall 11. It has also been observed that the size of the electromagnetic field on the gangways 12 is reduced by decreasing the ratio between the thickness and the width of the bars 9 and 10. It is therefore preferable to use horizontal plates or sheets for the busbars 9 and 10.

In the embodiment schematized in FIG. 4, in which the secondary circuit has likewise not been represented, the return electrical current line 7 comprises a metal plate or sheet 14 which is attached to the lower wall 11 of the electrolyzer and which substantially covers all of this wall.

In the installation of FIG. 5, the electrical current line 7 comprises a metal plate 14 which is applied against the lower wall 11 of the electrolyzer 3, and two additional busbars 15 and 16 which respectively run along the two side walls 13 of the electrolyzer 3. The two additional busbars 15 and 16 are advantageously metal plates or sheets which are attached to the side walls 13.

In the installations of FIGS. 6 and 7, which are similar to FIGS. 4 and 5, the circuit 17a, 17b has been represented. The current flows in the conductors 17b in an opposite direction to that flowing in the plate 14. The same is true for the conductors 17a and the plates 15 and 16.

1-14. (canceled)

15: An electrical circuit for reducing electromagnetic fields in a vicinity of an electrolyzer, comprising:
a primary electrical circuit, comprising the electrolyzer and an electrical line comprising at least one busbar for returning current flowing in the electrolyzer; and
a secondary electrical circuit at least partially arranged in a vicinity of the primary circuit, for a current to flow in an opposite direction to current flowing in the main circuit to compensate for an electromagnetic field generated by the primary circuit.

16: A circuit according to claim 15, wherein the busbar is positioned below and/or above the electrolyzer.

17: A circuit according to claim 15, wherein the busbar is attached to a wall of the electrolyzer.

18: A circuit according to claim 17, wherein the wall is a bottom wall of the electrolyzer.

19: A circuit according to claim 17, wherein the busbar is a metal plate, one of large faces of the busbar being attached to the wall.

20: A circuit according to claim 18, wherein the busbar is a metal plate, one of large faces of the busbar being attached to the wall.

21: A circuit according to claim 15, wherein the electrical line further comprises two additional busbars, which are respectively attached to two side walls of the electrolyzer.

22: A circuit according to claim 15, wherein the electrical line is positioned so as to generate an electromagnetic field that is substantially symmetrical with respect to a vertical median plane of the electrolyzer.

23: A circuit according to claim 15, wherein the electrolyzer comprises a conduit for continuous intake of an aqueous electrolyte and a conduit for continuous discharge of an aqueous electrolyte.

24: A circuit according to claim 23, wherein the electrolyzer comprises two membranes selectively permeable to cations, which are interposed between the bipolar electrodes.

25: A circuit according to claim 15, wherein the primary circuit comprises a supply using two rectifiers to deliver currents whose waveforms are phase-shifted with respect to one another.

26: A circuit according to claim 25, further comprising a drain coil coupling outputs of the two rectifiers.

27: A method for reducing electromagnetic fields in a vicinity of an electrical circuit of an electrolyzer including a primary electrical circuit, itself including the electrolyzer and an electrical line including at least one busbar for returning current flowing in the electrolyzer, according to which an electrical current is passed through a secondary electrical circuit, arranged in a vicinity of the primary circuit, in an opposite direction to current flowing in the primary circuit.

28: A method according to claim 27, wherein the primary circuit includes a supply using two rectifiers to deliver currents whose waveforms are phase-shifted by 30° with respect to one another.

29: A method according to claim 28, wherein the primary circuit further includes a drain coil coupling outputs of the two rectifiers.
